(19) United States
(12) Patent Application Publication
(10) Pub. No.: US 2026/0059893 A1
(43) Pub. Date: Feb. 26, 2026

(54) QUANTUM DOT ENSEMBLE AND LIGHT DETECTION DEVICE AND ELECTRONIC APPARATUS

(71) Applicants: SONY SEMICONDUCTOR SOLUTIONS CORPORATION, KANAGAWA (JP); SONY GROUP CORPORATION, Tokyo (JP)

(72) Inventors: HIROTAKA MIZUSHIMA, TOKYO (JP); MAMORU TANABE, TOKYO (JP); SYUUITI TAKIZAWA, KANAGAWA (JP); SHINJI TANAKA, TOKYO (JP); MASAHIRO KIKKAWA, TOKYO (JP)

(21) Appl. No.: 19/104,854

(22) PCT Filed: Aug. 15, 2023
(86) PCT No.: PCT/JP2023/029491

§ 371 Date: Feb. 19, 2025

(30) Foreign Application Priority Data
Aug. 26, 2022 (JP) 2022-135014

(51) Int. Cl. H10F 77/14; B82Y 20/00; H10F 30/22; H10F 39/18

(52) U.S. Cl. CPC H10F 77/1433; B82Y 20/00; H10F 30/22; H10F 39/18

(57) ABSTRACT

A quantum dot ensemble of an embodiment of the present disclosure includes a plurality of quantum dots (120) each including a core (121) including a compound semiconductor and a shell layer (122) including one or more organic ligands (122A) coordinated to a surface of the core (121) and an oxide film (122B) that covers a portion of the surface of the core (121) to which the one or more organic ligands (122A) are not coordinated, and adjacent quantum dots of the plurality of quantum dots (120) are adjacent through the one or more organic ligands (122A) or the oxide film (122B).

### TECHNICAL FIELD

The present disclosure relates to a quantum dot ensemble and a light detection device and an electronic apparatus.

### BACKGROUND ART

For example, PTL 1 discloses a solar cell having a quantum dot layer including quantum dots and a matrix containing the quantum dots on a principal surface of a semiconductor substrate.

### CITATION LIST

### Patent Literature

PTL 1: Japanese Unexamined Patent Application Publication No. 2013-211418

### SUMMARY OF INVENTION

Incidentally, reduction of dark current is expected of a light detection device.

It is desirable to provide a quantum dot ensemble and a light detection device and an electronic apparatus that make it possible to reduce dark current.

A quantum dot ensemble of an embodiment of the present disclosure includes a plurality of quantum dots each including: a core including a compound semiconductor; and a shell layer including one or more organic ligands coordinated to a surface of the core and an oxide film that covers a portion of the surface of the core to which the one or more organic ligands are not coordinated, in which adjacent quantum dots of the plurality of quantum dots are adjacent through the one or more organic ligands or the oxide film.

A light detection device of an embodiment of the present disclosure includes: a second electrode provided to be opposed to a first electrode; and a photoelectric conversion layer provided between the first electrode and the second electrode, and the photoelectric conversion layer includes the quantum dot ensemble of the embodiment of the present disclosure described above.

An electronic apparatus of an embodiment of the present disclosure includes the light detection device of the embodiment of the present disclosure described above.

In the quantum dot ensemble, the light detection device, and the electronic apparatus of the embodiments of the present disclosure, the one or more organic ligands are coordinated to the surface of the core including the compound semiconductor, and a portion of the surface of the core to which no organic ligands are coordinated is covered with the oxide film. This suppresses a surface defect of the quantum dot.

### BRIEF DESCRIPTION OF DRAWINGS

FIG. 1 is a schematic cross-sectional view illustrating a configuration of a quantum dot according to an embodiment of the present disclosure.

FIG. 2 is a diagram that describes the state of multiple quantum dots in an ensemble of the quantum dots illustrated in FIG. 1.

FIG. 3 is a block diagram illustrating an entire configuration of a light detection device according to an embodiment of the present disclosure.

FIG. 4 is a schematic cross-sectional view illustrating a configuration of each unit pixel of the light detection device illustrated in FIG. 3.

FIG. 5 is an equivalent circuit diagram of each unit pixel of the light detection device illustrated in FIG. 3.

FIG. 6 is a schematic cross-sectional view illustrating a configuration of each unit pixel of a light detection device according to a modification example of the present disclosure.

FIG. 7 is a block diagram illustrating an example of a configuration of an electronic apparatus using the light detection device illustrated in FIG. 1.

FIG. 8A is a schematic diagram illustrating an example of an entire configuration of a light detection system including the light detection device illustrated in FIG. 1.

FIG. 8B is a diagram illustrating an example of a circuit configuration of the light detection system illustrated in FIG. 8A.

FIG. 9 is a view depicting an example of a schematic configuration of an endoscopic surgery system.

FIG. 10 is a block diagram depicting an example of a functional configuration of a camera head and a camera control unit (CCU).

FIG. 11 is a block diagram depicting an example of schematic configuration of a vehicle control system.

FIG. 12 is a diagram of assistance in explaining an example of installation positions of an outside-vehicle information detecting section and an imaging section.

### MODES FOR CARRYING OUT THE INVENTION

With reference to the drawings, embodiments of the present disclosure will be described in detail below. The following description is a specific example of the present disclosure, and the present disclosure is not limited to the following aspects. Furthermore, as for the layout, dimensions, dimensional ratio, etc. of each component illustrated in each drawing, the present disclosure is not limited to those. It is to be noted that the order of description is as follows.

### 1. Embodiment (an Example of a Light Detection Device Including a Photoelectric Conversion Layer Using Quantum Dots)

1-1. Configuration of Quantum Dot
1-2. Method for Producing Quantum Dot
1-3. Configuration of Light Detection Device
1-4. Actions and Effects

### 2. Modification Example

### 3. Application Examples

### 4. Practical Application Examples

### 1. Embodiment

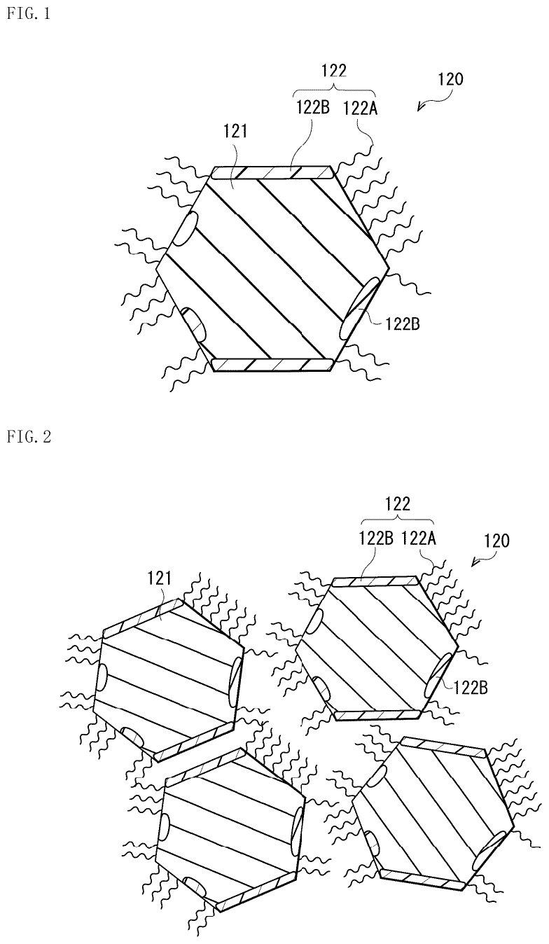

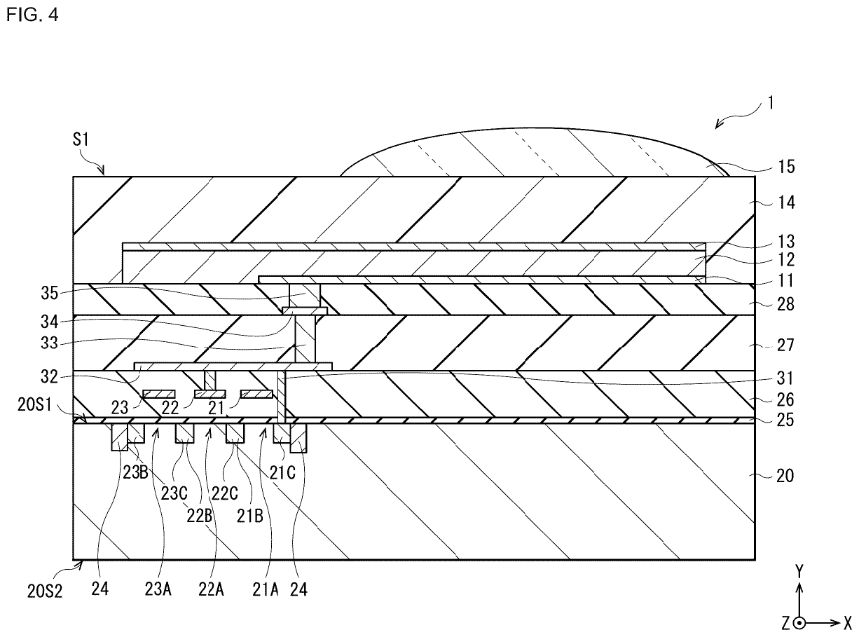

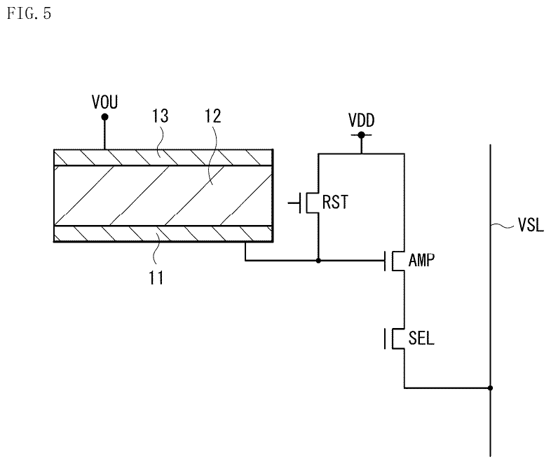

FIG. 1 is a schematic cross-sectional view illustrating a configuration of a quantum dot (a quantum dot 120) according to an embodiment of the present disclosure. The quantum dot 120 is used, for example, as a material of a photoelectric conversion layer 12 of a light detection device 1 to be described later (see, for example, FIG. 4). The quantum dot 120 of the present embodiment is a core-shell quantum dot including a core 121 and a shell layer 122, and the shell layer 122 includes one or more organic ligands 122A coordinated to a surface of the core 121 and an oxide film 122B formed on a portion of the surface of the core 121 to which the one or more organic ligands 122A are not coordinated. In the photoelectric conversion layer 12 (a quantum dot ensemble) using multiple quantum dots 120 formed in layers, the multiple quantum dots 120 in the layer are adjacent to one another through the organic ligands 122A or the oxide film 122B (see FIG. 2).

### 1-1. Configuration of Quantum Dot

As described above, the quantum dot 120 includes the core 121 and the shell layer 122 that covers the surface of the core 121.

The core 121 is a semiconductor nanoparticle including a compound semiconductor. Specifically, the core 121 includes, for example, a compound semiconductor of group IV-VI, III-V, II-VI, I-VI, or I-III-VI or a compound semiconductor including a combination of three or more kinds of elements of groups I, III, IV, V, and VI.

Examples of group IV-VI compound semiconductors include PbO, PbS, PbSe, PbTe, and the like. Examples of group III-V compound semiconductors include GaAs, InAs, InP, AlGaAs, InGaP, AlGaInP, and the like. Examples of group II-VI compound semiconductors include CdS, CdSe, CdTe, ZnO, ZnS, ZnSe, ZnTe, HgTe, and the like. Examples of group I-III-VI compound semiconductors include chalcopyrite-based semiconductors such as CuInGaSe, CuInSe₂, CuInS₂, CuAlS₂, CuAlSe₂, CuGaS₂, CuGaSe₂, CuZnSnSSe, ZnCuInSe, AgAlS₂, AgAlSe₂, AgInS₂, and AgInSe₂. Besides these, examples of the compound semiconductor included in the core 121 include GaP, InN, InSb, InGaAs, InGaAsP, GaN, CdSeS, In₂Se₃, In₂S₃, Bi₂Se₃, Bi₂S₃, HgS, TiO₂, AgS, AgSe, AgTe, and the like.

The shell layer 122 includes the one or more organic ligands 122A and the oxide film 122B, and, for example, has an amorphous structure. The shell layer 122 includes, for example, the same element as the core 121.

The one or more organic ligands 122A are an organic compound forming a coordinate bond to a metal ion. The one or more organic ligands 122A are coordinately bonded to the core 121 including the compound semiconductor, thereby inactivating a highly reactive defect (a dangling bond) present on the surface of the core 121. The one or more organic ligands 122A include one or both of basic group and weak acid group. Specifically, the one or more organic ligands 122A include one or both of thiol group and carboxyl group with a carbon number of 5 or less.

It is to be noted that if the length of the one or more organic ligands 122A becomes longer, there is a possibility of degradation in mobility of charge carriers between the quantum dots 120. Thus, it is preferable that the length of the one or more organic ligands 122A be, for example, 0.6 nm or less.

The oxide film 122B covers a portion of the surface of the core 121 to which the one or more organic ligands 122A are not coordinated. The oxide film 122B is a surface oxide film made by oxidizing the surface of the core 121, and a defect of the surface of the core 121 is suppressed by this oxide film 122B. It is preferable that the thickness of the oxide film 122B be, for example, 0.6 nm or less, as with the length of the one or more organic ligands 122A.

That is, it is preferable that the thickness of the shell layer 122 be 0.6 nm or less.

In the quantum dot 120 of the present embodiment, the bonding state of each element included in the core 121 to oxygen is detected by X-ray photoelectron spectroscopic analysis. Furthermore, in an element having the smallest atomic number among elements included in the core 121, the integrated intensity of a peak (a first peak) derived from the bonding to oxygen with respect to the integrated intensity of a peak (a second peak) derived from the bonding of the core 121 and the one or more organic ligands 122A is 0.1 or more and 0.3 or less. That is, the ratio of a component of the one or more organic ligands 122A to a component of the oxide film 122B on the surface of the core 121 (a component of the oxide film 122B/a component of the core 121+a component of the one or more organic ligands 122A) is 0.1 or more and 0.3 or less. One reason for this is that if the intensity ratio is less than 0.1, the oxide film 122B is too thin, and does not exert the effect of defect suppression sufficiently. Furthermore, if the intensity ratio is more than 0.3, the oxide film 122B is too thick, and adversely affects the mobility of charge carriers.

It is to be noted that one reason why the component of the core 121 is included in the above-described expression for the component ratio is because of the detection depth of a measurement. A measured result includes the contributions of the organic ligands 122A and the oxide film 122B formed on a surface of the quantum dot 120 as well as the core 121 located on the slightly inside of them.

In a quantum dot ensemble of multiple quantum dots 120 formed, for example, in layers, the multiple quantum dots 120 in the layer are adjacent to one another through the organic ligands 122A or the oxide film 122B as illustrated in FIG. 2.

### 1-2. Method for Producing Quantum Dot

The quantum dot 120 is able to be formed by using, for example, the following two methods.

### [Method 1 for Producing Quantum Dot]

First, quantum dot ink including a core 121 with a long ligand coordinated is applied onto a substrate to form a film. Then, dispersing liquid for a short ligand corresponding to an organic ligand 122A is applied onto the film. By doing this, the ligand on a surface of the core 121 is exchanged from the long ligand to the short ligand. After that, under an atmosphere of oxygen partial pressure of 20% to 100%, it is heated in a range of 40° C. to 150° C. By doing this, a shell layer 122 including one or more organic ligands 122A and an oxide film 122B is formed on the surface of core 121.

### [Method 2 for Producing Quantum Dot]

First, salt is added to quantum dot ink including a core 121 with a long ligand coordinated to remove the long ligand. Then, dispersing liquid for a short ligand corresponding to an organic ligand 122A is added to the ionized quantum dot ink, and, after the short ligand is coordinated to the core 121, this quantum dot ink is applied to a substrate. After that, under an atmosphere of oxygen partial pressure of 20% to 100%, it is heated in a range of 40° C. to 150° C. By doing this, a shell layer 122 including one or more organic ligands 122A and an oxide film 122B is formed on the surface of core 121.

The ratio of a component of the one or more organic ligands 122A to a component of the oxide film 122B before and after the formation of the shell layer 122 of the quantum dot 120 formed by using the above-described method (a component of the oxide film 122B/a component of the core 121+a component of the one or more organic ligands 122A) and dark current before and after the formation of the shell layer 122 of an ensemble of the quantum dots 120 formed in layers change as illustrated in Table 1. It is to be noted that as for the dark current, a relative value in a case where a value before the formation is 1.0 is written.

TABLE 1

| | BEFORE | AFTER |
|---|---|---|
| | FORMATION | FORMATION |
| | OF SHELL | OF SHELL |
| | LAYER | LAYER |
| COMPONENT OF OXIDE | 0.10 | 0.24 |
| FILM/COMPONENT OF | | |
| CORE + COMPONENT OF | | |
| ORGANIC LIGAND | | |
| DARK CURRENT@2 V (A/cm²) | 1.0 | 0.03 |

### 1-3. Configuration of Light Detection Device

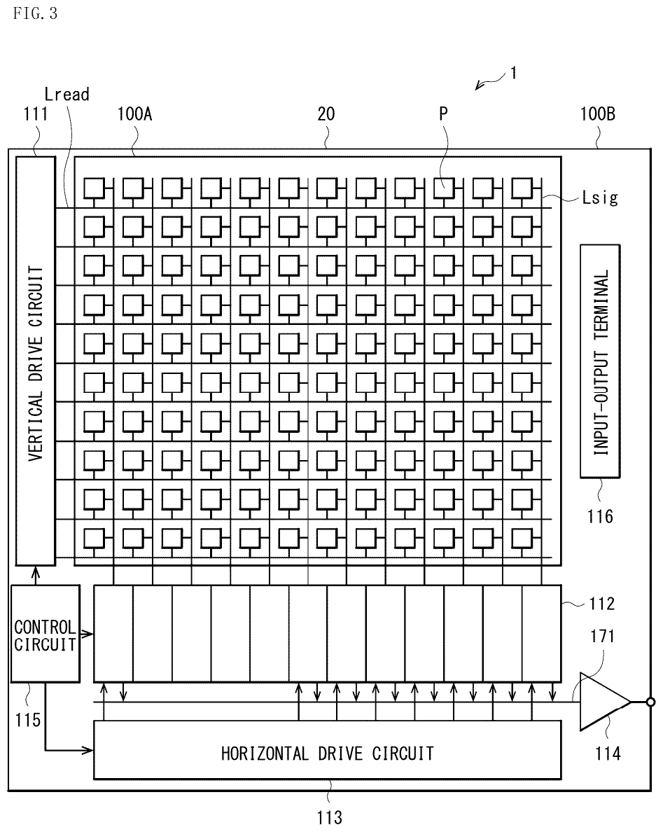

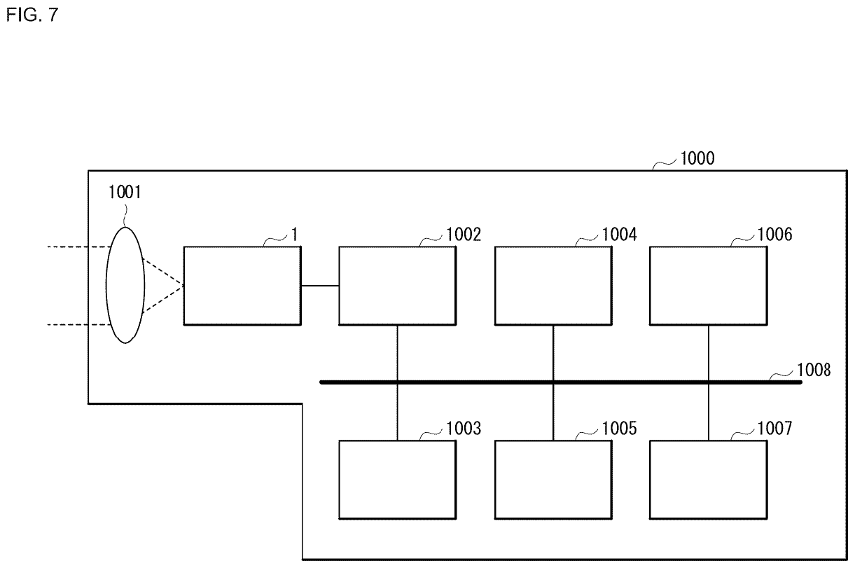

FIG. 3 illustrates an example of an entire configuration of a light detection device (a light detection device 1) according to an embodiment of the present disclosure. The light detection device 1 is used, for example, an electronic apparatus (an electronic apparatus 1000, see FIG. 7) such as a complementary metal-oxide semiconductor (CMOS) image sensor used in an electronic apparatus such as a digital still camera or a video camera.

For example, the light detection device 1 takes in incident light (image light) from a subject through an optical lens system (not illustrated), and converts an amount of incident light formed as an image on an imaging plane into an electrical signal on a pixel-by-pixel basis, and outputs the electrical signal as a pixel signal. The light detection device 1 includes, on a semiconductor substrate 20, a pixel section 100A as an imaging area, and, in a region around this pixel section 100A, for example, a vertical drive circuit 111, a column signal processing circuit 112, a horizontal drive circuit 113, an output circuit 114, a control circuit 115, and an input-output terminal 116.

The pixel section 100A includes, for example, a plurality of unit pixels P two-dimensionally arranged in a matrix. These unit pixels P are provided with, for example, a pixel drive line Lread (specifically, a row selection line and a reset control line) for each pixel row and a vertical signal line Lsig for each pixel column. The pixel drive line Lread is for transmitting a drive signal for readout of a signal from a unit pixel P. One end of the pixel drive line Lread is coupled to an output terminal of the vertical drive circuit 111 corresponding to each row.

The vertical drive circuit 111 is a pixel drive unit that includes a shift register, an address decoder, etc., and drives each unit pixel P in the pixel section 100A, for example, on a row-by-row basis. A signal output from each of unit pixels P of a pixel row selected and scanned by the vertical drive circuit 111 is supplied to the column signal processing circuit 112 through a vertical signal line Lsig. The column signal processing circuit 112 includes an amplifier, a horizontal selection switch, etc. provided for each vertical signal line Lsig.

The horizontal drive circuit 113 includes a shift register, an address decoder, etc., and drives each horizontal selection switch of the column signal processing circuit 112 in turn while scanning. By this selective scanning by the horizontal drive circuit 113, a signal of each pixel transmitted through a respective vertical signal line Lsig is output to a horizontal signal line 117 in turn, and is transmitted to the outside of the semiconductor substrate 20 through the horizontal signal line 117.

The output circuit 114 performs signal processing on signals sequentially supplied from each of the column signal processing circuits 112 through the horizontal signal line 117 and outputs the processed signals. For example, the output circuit 114 performs only buffering in some cases, and performs black level adjustment, column variation correction, a variety of digital signal processing, etc. in other cases.

A circuit part including the vertical drive circuit 111, the column signal processing circuit 112, the horizontal drive circuit 113, the horizontal signal line 117, and the output circuit 114 may be formed on the semiconductor substrate 20, or may be provided in an external control IC. Furthermore, the circuit part may be formed on another substrate coupled by cable or something.

The control circuit 115 receives a clock given from the outside of the semiconductor substrate 20, data that orders an operation mode, etc., and outputs data such as internal information of the light detection device 1. Furthermore, the control circuit 115 includes a timing generator that generates various timing signals, and performs control of driving the peripheral circuits such as the vertical drive circuit 111, the column signal processing circuit 112, and the horizontal drive circuit 113 on the basis of various timing signals generated by the timing generator.

The input-output terminal 116 exchanges a signal with the outside.

FIG. 4 schematically illustrates an example of a cross-sectional configuration of each unit pixel P of the light detection device 1 illustrated in FIG. 3. FIG. 5 is an equivalent circuit diagram of each unit pixel P of the light detection device 1 illustrated in FIG. 4.

The light detection device 1 is provided with, for example, on the side of a surface 20S1 that is the light incident side S1 of the semiconductor substrate 20 having a pair of surfaces (the surface 20S1 and a surface 20S2) opposed to each other, a photoelectric converter 10 that absorbs light corresponding to all or a part of wavelengths in a selective wavelength region (for example, a visual light region and a near-infrared region of 400 nm or more and less than 1600 nm) and generates an exciton (an electron-hole pair). The photoelectric converter 10 includes the photoelectric conversion layer 12 between a lower electrode 11 (for example, a first electrode) and an upper electrode 13 (for example, a second electrode) that are provided to be opposed to each other. In the photoelectric converter 10, of an electron-hole pair generated through photoelectric conversion, for example, an electron is read as a signal charge out from the lower electrode 11 side. In the following, a configuration, a material, etc. of each unit is described, as an example, in a case where an electron is read as a signal charge out from the lower electrode 11 side.

The lower electrode 11 includes, for example, a light-transmissive conductive film. Examples of a constituent material of the lower electrode 11 include indium tin oxide (ITO) that is In₂O₃ doped with tin (Sn) as a dopant. Besides the above, the examples of a constituent material of the lower electrode 11 include dopant-doped tin oxide (SnO₂)-based materials, for example, ATO doped with Sb as a dopant and FTO doped with fluorine as a dopant. Furthermore, zinc oxide (ZnO) or a zinc oxide-based material doped with a dopant may be used. Examples of ZnO-based materials include aluminum zinc oxide (AZO) doped with aluminum (Al) as a dopant, gallium zinc oxide (GZO) doped with gallium (Ga), boron zinc oxide doped with boron (B), and indium zinc oxide (IZO) doped with indium (In). Furthermore, zinc oxide doped with indium and gallium as dopants (IGZO, In—GaZnO₄) may be used. In addition, as a constituent material of the lower electrode 11, a material such as Cul, InSbO₄, ZnMgO, CuInO₂, MgIN₂O₄, CdO, ZnSnO₃, or TiO₂ may be used, or spinel-type oxide or oxide having a YbFe₂O₄ structure may be used.

Furthermore, in a case where the lower electrode 11 does not have to be light-transmissive, monometal or alloy having a low work function (for example, ϕ=3.5 eV to 4.5 eV) is able to be used. Specifically, alkali metal (for example, lithium (Li), sodium (Na), potassium (K), or the like) and its fluoride or oxide and alkaline earth metal (for example, magnesium (Mg), calcium (Ca), or the like) and its fluoride or oxide are able to be used. Besides these, rare earth metal such as aluminum (Al), Al—Si—Cu alloy, zinc (Zn), tin (Sn), thallium (Tl), Na—K alloy, Al—Li alloy, Mg—Ag alloy, In, and ytterbium (Yb) or alloys of those are able to be used.

Furthermore, as a material constituting the lower electrode 11, metal such as platinum (Pt), gold (Au), palladium (Pd), chromium (Cr), nickel (Ni), aluminum (Al), silver (Ag), tantalum (Ta), tungsten (W), copper (Cu), titanium (Ti), indium (In), tin (Sn), iron (Fe), cobalt (Co), and molybdenum (Mo) or alloy including a metallic element of those, or a conducting substance such as conducting particles including those metals, conducting particles of alloys including those metals, impurity-containing polysilicon, a carbon-based material, an oxide semiconductor, a carbon nanotube, or graphene is able to be used. Besides these, as a material constituting the lower electrode 11, an organic material (a conducting polymer) such as poly(3,4-ethylenedioxythiophene)/polystyrene sulfonate [PEDOT/PSS] is able to be used. Moreover, the above-described material may be mixed with a binder (a polymer) to make a paste or ink, and it may be hardened and used as an electrode.

The lower electrode 11 is able to be formed as a single-layer film or a multi-layered film including the above-described material. A film thickness (hereinafter, referred to simply as thickness) of the lower electrode 11 in a stacking direction is, for example, 20 nm or more and 200 nm or less, preferably, 30 nm or more and 150 nm or less.

The photoelectric conversion layer 12 converts light energy into electric energy, and absorbs, for example, 60% or more of a predetermined wavelength included in at least a range from the visual light region to the near-infrared region to separate a charge. For example, the photoelectric conversion layer 12 absorbs light of all or a part of wavelengths in the visual light region and the near-infrared region of 400 nm or more and less than 1600 nm. The photoelectric conversion layer 12 corresponds to a specific example of a “quantum dot ensemble”, and the photoelectric conversion layer 12 includes multiple quantum dots described above.

The thickness of the photoelectric conversion layer 12 is, for example, 10 nm or more and 300 nm or less, preferably, 30 nm or more and 150 nm or less.

As with the lower electrode 11, the upper electrode 13 includes, for example, a light-transmissive conductive film. Examples of a constituent material of the upper electrode 13 include indium tin oxide (ITO) that is In₂O₃ doped with tin (Sn) as a dopant. The crystallinity of an ITO thin film may be high in crystallinity, or may be low (close to amorphous). Besides the above, the examples of a constituent material of the upper electrode 13 include dopant-doped tin oxide (SnO₂)-based materials, for example, ATO doped with Sb as a dopant and FTO doped with fluorine as a dopant. Furthermore, zinc oxide (ZnO) or a zinc oxide-based material doped with a dopant may be used. Examples of ZnO-based materials include aluminum zinc oxide (AZO) doped with aluminum (Al) as a dopant, gallium zinc oxide (GZO) doped with gallium (Ga), boron zinc oxide doped with boron (B), and indium zinc oxide (IZO) doped with indium (In). Furthermore, zinc oxide doped with indium and gallium as dopants (IGZO, In—GaZnO₄) may be used. In addition, as a constituent material of the upper electrode 13, a material such as Cul, InSbO₄, ZnMgO, CuInO₂, MgIN₂O₄, CdO, ZnSnO₃, or TiO₂ may be used, or spinel-type oxide or oxide having a YbFe₂O₄ structure may be used.

Furthermore, in a case where the upper electrode 13 does not have to be light-transmissive, monometal or alloy having a high work function (for example, ϕ=4.5 eV to 5.5 eV) is able to be used. Specifically, for example, Au, Ag, Cr, Ni, Pd, Pt, Fe, iridium (Ir), germanium (Ge), osmium (Os), rhenium (Re), tellurium (Te), and alloys of those are able to be used.

Furthermore, as a material constituting the upper electrode 13, metal such as Pt, Au, Pd, Cr, Ni, Al, Ag, Ta, W, Cu, Ti, In, Sn, Fe, Co, and Mo or alloy including a metallic element of those, or a conducting substance such as conducting particles including those metals, conducting particles of alloys including those metals, impurity-containing polysilicon, a carbon-based material, an oxide semiconductor, a carbon nanotube, or graphene is able to be used. Besides these, as a material constituting the upper electrode 13, an organic material (a conducting polymer) such as PEDOT/PSS is able to be used. Moreover, the above-described material may be mixed with a binder (a polymer) to make a paste or ink, and it may be hardened and used as an electrode.

The upper electrode 13 is able to be formed as a single-layer film or a multi-layered film including the above-described material. A thickness of the upper electrode 13 is, for example, 20 nm or more and 200 nm or less, preferably, 30 nm or more and 150 nm or less.

It is to be noted that another layer may be provided between the lower electrode 11 and the upper electrode 13. For example, a hole blocking layer or an undercoating layer may be provided between the lower electrode 11 and the photoelectric conversion layer 12. An electron blocking layer or a work function adjustment layer may be provided between the photoelectric conversion layer 12 and the upper electrode 13. The hole blocking layer selectively transports, of charge carriers generated in the photoelectric conversion layer 12, electrons to the lower electrode 11, and blocks the injection of holes from the lower electrode 11 side. The electron blocking layer selectively transports, of charge carriers generated in the photoelectric conversion layer 12, holes to the upper electrode 13, and blocks the injection of electrons from the upper electrode 13 side. The work function adjustment layer has an electron affinity or a work function that is greater than a work function of the upper electrode 13.

In the photoelectric converter 10, light that has entered from the upper electrode 13 side to the photoelectric converter 10 is absorbed by the photoelectric conversion layer 12. An exciton caused by this is split and dissociated into an electron and a hole. Charge carriers (the electron and the hole) generated here are transported to different electrodes by diffusion caused by a difference in concentration of the charge carriers and an internal electric field caused by a difference in work function between an anode (for example, the upper electrode 13) and a cathode (for example, the lower electrode 11), and are detected as a photocurrent. Directions of transporting the electron and the hole are controlled by applying an electrical potential to between the lower electrode 11 and the upper electrode 13.

The semiconductor substrate 20 includes, for example, an n-type silicon (Si) substrate. On the surface 20S1 of the semiconductor substrate 20, for example, a floating diffusion (a floating diffusion layer) FD (a region 21C within the semiconductor substrate 20), an amplifier transistor (a modulation element) AMP, a reset transistor RST, a selection transistor SEL, and an isolation region 24 are provided. Furthermore, peripheral circuits (not illustrated) including a logic circuit, etc. are provided in the periphery of the semiconductor substrate 20.

Between the surface 20S1 of the semiconductor substrate 20 and the lower electrode 11 of the photoelectric converter 10, for example, an insulating layer 25, interlayer insulating layers 26, 27, and 28 are provided in this order on the side of the surface 20S1. A planarizing layer 14 is provided on the upper electrode 13 of the photoelectric converter 10, and an optical member such as an on-chip lens 15 is provided on the planarizing layer 14.

A reset gate 21 of the reset transistor RST is disposed adjacent to the floating diffusion FD (a region 21B). This makes it possible for the reset transistor RST to reset charge carriers accumulated in the floating diffusion FD.

The reset transistor RST resets charge carriers transferred from the photoelectric converter 10 to the floating diffusion FD, and includes, for example, a MOS transistor. Specifically, the reset transistor RST includes the reset gate 21, a channel formation region 21A, and source/drain regions 21B and 21C. The reset gate 21 is coupled to a reset line, and the source/drain region 21C of the reset transistor RST also serves as the floating diffusion FD. The other source/drain region 21B included in the reset transistor RST is coupled to a power source VDD.

The amplifier transistor AMP is a modulation element that modulates an amount of electric charge generated in the photoelectric converter 10 into a voltage, and includes, for example, a MOS transistor. Specifically, the amplifier transistor AMP includes an amplifying gate 22, a channel formation region 22A, and source/drain regions 22B and 22C. The amplifying gate 22 is coupled to the lower electrode 11 and the source/drain region 21C (the floating diffusion FD) of the reset transistor RST through a via and a through-wiring 31 that are provided in the interlayer insulating layer 26, a wiring 32 and a through-wiring 33 that are provided in the interlayer insulating layer 27, a wiring 34 and a contact 35 that are provided in the interlayer insulating layer 28, etc. Furthermore, the source/drain region 22C shares the region with the source/drain region 21B included in the reset transistor RST, and is coupled to the power source VDD.

The selection transistor SEL includes a selection gate 23, a channel formation region 23A, and source/drain regions 23B and 23C. The selection gate 23 is coupled to a selection line. Furthermore, the source/drain region 23V shares the region with the source/drain region 22B included in the amplifier transistor AMP, and the other source/drain region 23B is coupled to a signal line (a data output line) VSL.

The reset line and the selection line are each coupled to a row scanning unit 131 included in a drive circuit. The signal line (the data output line) VSL is coupled to a horizontal selection unit 133 included in the drive circuit.

The isolation region 24 has a shallow trench isolation (STI) structure, and include, for example, silicon oxide.

The insulating layer 25 may be a film having a positive fixed charge, or may be a film having a negative fixed charge. As a material of the film having a negative fixed charge, a material such as hafnium oxide, aluminum oxide, zirconium oxide, tantalum oxide, or titanium oxide is used. Furthermore, as a material other than the above, a material such as lanthanum oxide, praseodymium oxide, cerium oxide, neodymium oxide, promethium oxide, samarium oxide, europium oxide, gadolinium oxide, terbium oxide, dysprosium oxide, hole mium oxide, thulium oxide, ytterbium oxide, lutetium oxide, yttrium oxide, aluminum nitride film, hafnium oxynitride film, or aluminum oxynitride film may be used.

The interlayer insulating layers 26, 27, and 28 include, for example, a single-layer film including, of materials such as silicon oxide, silicon nitride, and silicon oxynitride (SiON), one or a multi-layered film including two or more of these materials.

The reset gate 21, the amplifying gate 22, the selection gate 23, the through-wirings 31 and 33, the wirings 32 and 34, and the contact 35 include, for example, a doped silicon material, such as phosphorus-doped amorphous silicon (PDAS), or a metal material, such as aluminum (Al), tungsten (W), titanium (Ti), cobalt (Co), hafnium (Hf), or tantalum (Ta).

The planarizing layer 14 includes a light-transmissive material, and includes, for example, a single-layer film including any of materials such as silicon oxide, silicon nitride, and silicon oxynitride or a multi-layered film including two or more of these materials. The thickness of the planarizing layer 14 is, for example, 100 nm to 30000 nm. The on-chip lens 15 includes a light-transmissive material, as with the planarizing layer 14.

### 1-4. Actions and Effects

In the quantum dot 120 of the present embodiment, the shell layer 122 that covers the surface of the core 121 includes the one or more organic ligands 122A coordinated to the surface of the core 121 and the oxide film 122B formed on a portion of the surface of the core 121 to which the one or more organic ligands 122A are not coordinated. This suppresses a surface defect of the quantum dot 120. This is described below.

In a case where a colloidal quantum dot is applied to a light sensor, to improve the mobility, the distance between quantum dots in an ensemble including quantum dots only is expected to be shortened. As a process for that, it is necessary to replace a ligand coordinated to a surface of a quantum dot with a shorter one. However, there are issues that at the time of the ligand replacement, a defect is likely to be generated on the surface of the quantum dot, and, in a sensor element using an ensemble of those quantum dots, there is an increase in dark current.

Meanwhile, in the present embodiment, in the core-shell quantum dot 120 including the core 121 and the shell layer 122, the shell layer 122 that covers the surface of the core 121 includes the one or more organic ligands 122A coordinated to the surface of the core 121 and the oxide film 122B formed on a portion of the surface of the core 121 to which the one or more organic ligands 122A are not coordinated. Thus, a surface defect of the quantum dot 120 is suppressed without reducing the mobility of charge carriers in the layers of the quantum dot ensemble of the quantum dots 120 formed, for example, into layers.

Consequently, in the quantum dot 120 of the present embodiment and the light detection device 1 including the photoelectric conversion layer 12 including an ensemble of the quantum dots 120, it is possible to reduce dark current.

Subsequently, a modification example of the present disclosure and application examples and practical application examples will be described. It is to be noted that a component corresponding to the light detection device 1 of the above-described embodiment is assigned the same reference numeral, and its description is omitted.

### 2. Modification Example

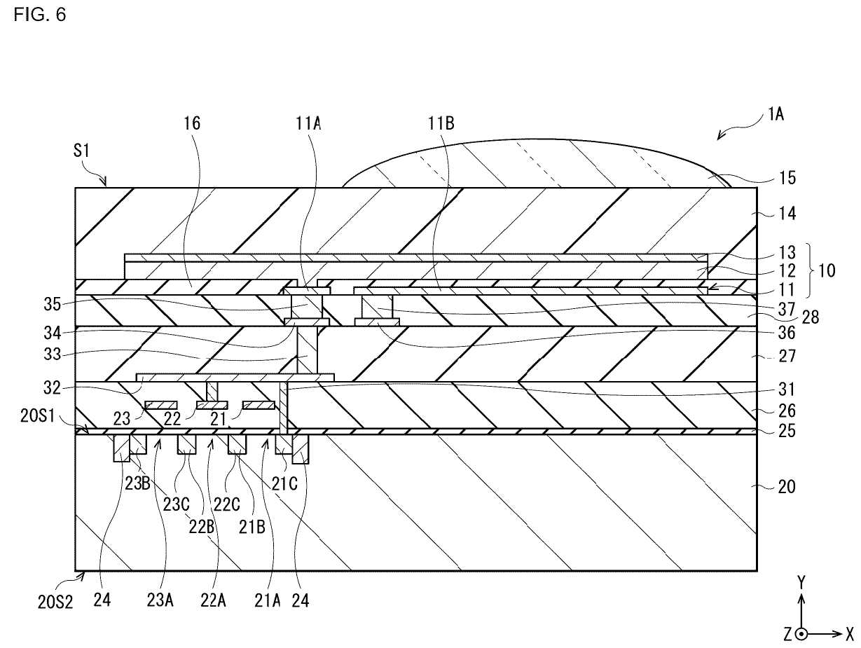

FIG. 6 schematically illustrates an example of a cross-sectional configuration of a light detection device (a light detection device 1A) according to a modification example of the present disclosure. As with the above-described light detection device 1, the light detection device 1A is used, for example, an electronic apparatus (the electronic apparatus 1000, see FIG. 7) such as a CMOS image sensor used in an electronic apparatus such as a digital still camera or a video camera. The light detection device 1A of the present modification example differs from the light detection device 1 in that the lower electrode 11 includes multiple electrodes (for example, two of a readout electrode 11A and an accumulation electrode 11B), and, for example, an insulating layer 16 is provided between the lower electrode 11 and the photoelectric conversion layer 12.

The readout electrode 11A is for transferring an electric charge generated in the photoelectric conversion layer 12 to the floating diffusion FD (the region 21C). For example, the readout electrode 11A is coupled to the floating diffusion FD through the through-wirings 31 and 33, the wirings 32 and 34, and the contact 35.

The accumulation electrode 11B is for accumulating, of charge carriers generated in the photoelectric conversion layer 12, electrons as a signal charge in the upper side. It is preferable that the accumulation electrode 11B be larger than the readout electrode 11A, thus it is possible to accumulate more charges. For example, the accumulation electrode 11B is coupled to a voltage applying unit (not illustrated) through wirings such as a wiring 36 and a contact 37.

The insulating layer 16 is for electrically separating the accumulation electrode 11B and the photoelectric conversion layer 12. The insulating layer 16 is provided, for example, on the interlayer insulating layer 28 to cover the lower electrode 11. The insulating layer 16 is provided with an opening on the readout electrode 11A, thus the readout electrode 11A and the photoelectric conversion layer 12 are electrically coupled.

The insulating layer 16 includes, for example, a single-layer film including, of materials such as silicon oxide, silicon nitride, and silicon oxynitride, one or a multi-layered film including two or more of these materials. The thickness of the insulating layer 16 is, for example, 20 nm or more and 500 nm or less.

It is to be noted that another layer may be provided between the insulating layer 16 and the photoelectric conversion layer 12. For example, a semiconductor layer with a higher charge mobility and a larger bandgap than the photoelectric conversion layer 12 may be provided between the insulating layer 16 and the photoelectric conversion layer 12. Examples of a material of the semiconductor layer include an oxide semiconductor, such as IGZO, an organic semiconductor, and the like. Examples of the organic semiconductor include transition metal dichalcogenide, silicon carbide, diamond, graphene, a carbon nanotube, condensed polycyclic hydrocarbon, condensed heterocyclic compound, and the like. By providing the semiconductor layer including the above-described material, a signal charge generated in the photoelectric conversion layer 12 is accumulated in the semiconductor layer, which makes it possible to reduce the charge recombination at the time of charge accumulation and improve the transfer efficiency.

Thus, the configuration of the light detection device is not limited to the light detection device 1 of the above-described embodiment, and the light detection device 1A of the present modification example is also able to achieve a similar effect to the above-described embodiment.

### 3. APPLICATION EXAMPLES

### Application Example 1

For example, the above-described light detection device 1 is applicable to various electronic apparatuses, for example, an imaging system such as a digital still camera or a digital video camera, a cell phone having an imaging function, and other devices having an imaging function.

FIG. 7 is a block diagram illustrating an example of a configuration of an electronic apparatus 1000.

As illustrated in FIG. 7, the electronic apparatus 1000 includes an optical system 1001, the light detection device 1, and a digital signal processor (DSP) 1002, and has a configuration in which the DSP 1002, a memory 1003, a display device 1004, a recording device 1005, an operation system 1006, and a power supply system 1007 are coupled through a bus 1008, and is able to take a still image and a moving image.

The optical system 1001 includes one or more lenses, and takes in incident light (image light) from a subject and forms an image on the imaging plane of the light detection device 1.

As the light detection device 1, the above-described light detection device 1 or 1A is applied. The light detection device 1 converts an amount of the incident light formed as an image on the imaging plane by the optical system 1001 into an electrical signal on a pixel-by-pixel basis, and supplies the electrical signal as a pixel signal to the DSP 1002.

The DSP 1002 performs various signal processing on the signal from the light detection device 1 and obtains an image, and temporarily stores data of the image in the memory 1003. The data of the image stored in the memory 1003 is recorded on the recording device 1005, or is supplied to the display device 1004 to display the image. Furthermore, the operation system 1006 receives various operations made by a user, and supplies an operation signal to each block of the electronic apparatus 1000, and the power supply system 1007 supplies electric power required to drive each block of the electronic apparatus 1000.

### Application Example 2

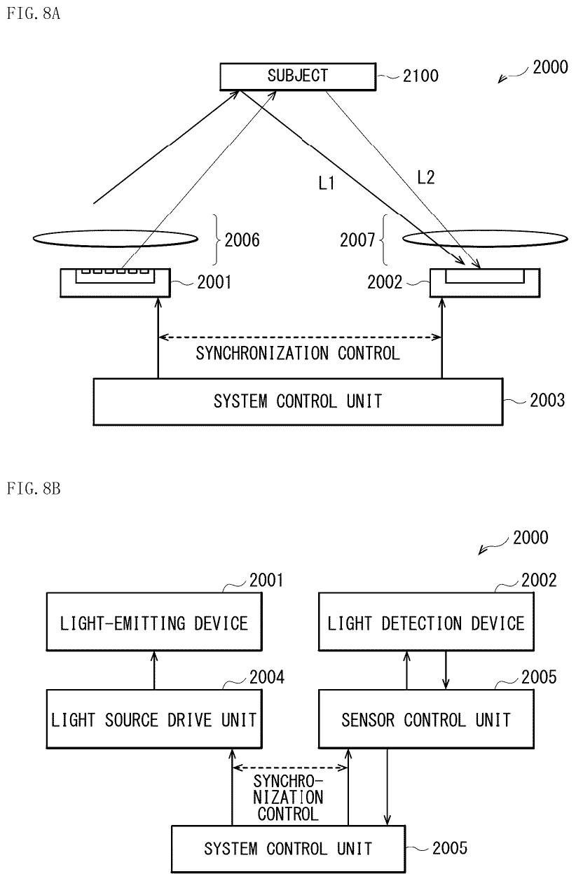

FIG. 8A schematically illustrates an example of an entire configuration of a light detection system 2000 including a light detection device (for example, the light detection device 1). FIG. 8B illustrates an example of a circuit configuration of the light detection system 2000. The light detection system 2000 includes a light-emitting device 2001 as a light source unit that emits infrared light L2 and a light detection device 2002 as a light receiving unit. For example, the above-described light detection device 1 is able to be used as the light detection device 2002. The light detection system 2000 may further include a system control unit 2003, a light source drive unit 2004, a sensor control unit 2005, a light-source-side optical system 2006, and a camera-side optical system 2007.

The light detection device 2002 is able to detect light L1 and light L2. The light L1 is light that ambient light from the outside has been reflected from a subject (an object to be measured) 2100 (FIG. 8A). The light L1 is, for example, visible light, and the light L2 is, for example, infrared light. The light L1 is able to be detected in a photoelectric converter of the light detection device 2002, and the light L2 is able to be detected in a photoelectric conversion region of the light detection device 2002. It is possible to acquire image information of the subject 2100 from the light L1 and acquire information regarding the distance between the subject 2100 and the light detection system 2000 from the light L2. The light detection system 2000 is able to be installed, for example, in an electronic apparatus such as a smartphone or a moving body such as a vehicle. The light-emitting device 2001 may include, for example, a semiconductor laser, a surface-emitting semiconductor laser, or a vertical-cavity surface-emitting laser (VCSEL). As a method for the light detection device 2002 to detect the light L2 emitted from the light-emitting device 2001, for example, the iTOF method is able to be adopted; however, it is not limited to this. In the iTOF method, the photoelectric converter is able to measure the distance from the subject 2100 on the basis of, for example, time-of-flight (TOF) of light. As a method for the light detection device 2002 to detect the light L2 emitted from the light-emitting device 2001, for example, the structured light method and the stereovision method are also able to be adopted. For example, in the structured light method, light of a predetermined pattern is projected onto the subject 2100, and the distance between the light detection system 2000 and the subject 2100 is able to be measured by analyzing a state of distortion of the pattern. Furthermore, in the stereovision method, two or more images of the subject 2100 viewed from two or more different viewpoints are acquired with, for example, two or more cameras, thereby the distance between the light detection system 2000 and the subject is able to be measured. It is to be noted that the light-emitting device 2001 and the light detection device 2002 are able to be synchronously controlled by the system control unit 2003.

### 4. Practical Application Examples

### Example of Practical Application to Endoscopic Surgery System

The technique according to the present disclosure (the present technology) is applicable to various products. For example, the technique according to the present disclosure may be applied to an endoscopic surgery system.

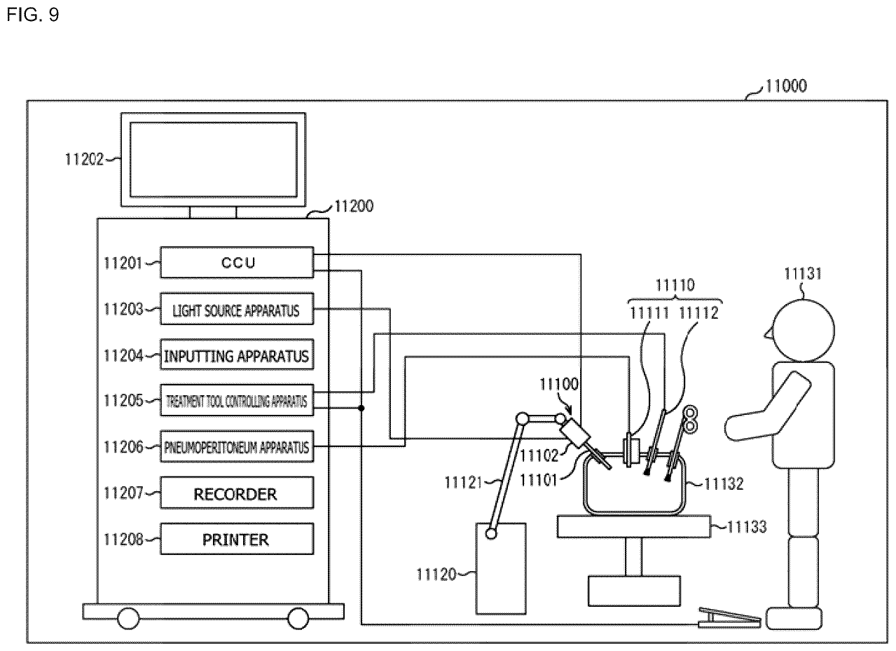

FIG. 9 is a view depicting an example of a schematic configuration of an endoscopic surgery system to which the technology according to an embodiment of the present disclosure (present technology) can be applied.

In FIG. 9, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

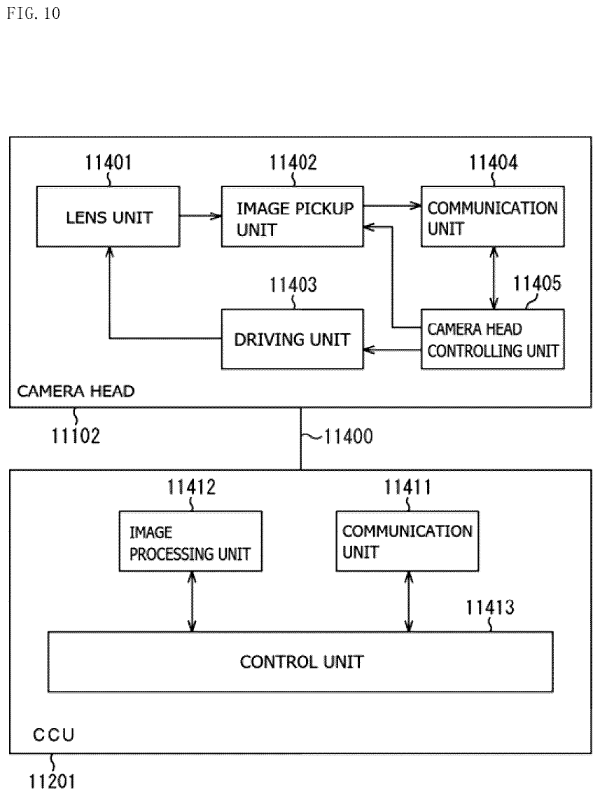

FIG. 10 is a block diagram depicting an example of a functional configuration of the camera head 11102 and the CCU 11201 depicted in FIG. 9.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

As above, there has been described an example of the endoscopic surgery system to which the technique according to the present disclosure may be applied. The technique according to the present disclosure may be applied to, of the above-described components, the image pickup unit 11402. By applying the technique according to the present disclosure to the image pickup unit 11402, the detection accuracy is improved.

It is to be noted that, here, there has been described the endoscopic surgery system as an example; however, the technique according to the present disclosure may be applied to other systems, for example, a micrographic surgery system or the like.

### Example of Practical Application to Moving Body

The technique according to the present disclosure is applicable to various products. For example, the technique according to the present disclosure may be realized as a device mounted on any of kinds of moving bodies such as a motor vehicle, an electric vehicle, a hybrid electric vehicle, a motorcycle, a bicycle, a personal transporter, an airplane, a drone, a vessel, a robot, construction equipment, and agricultural machinery (a tractor).

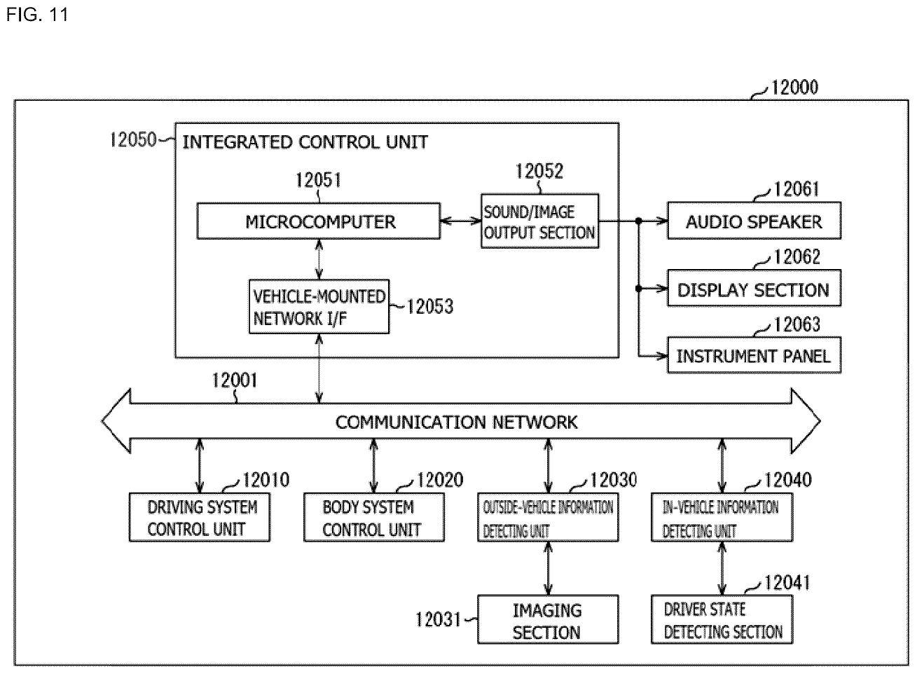

FIG. 11 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 11, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 11, an audio speaker 12061, a display section 12062, and an instrument panel 12063 are illustrated as the output device. The display section 12062 may, for example, include at least one of an on-board display and a head-up display.

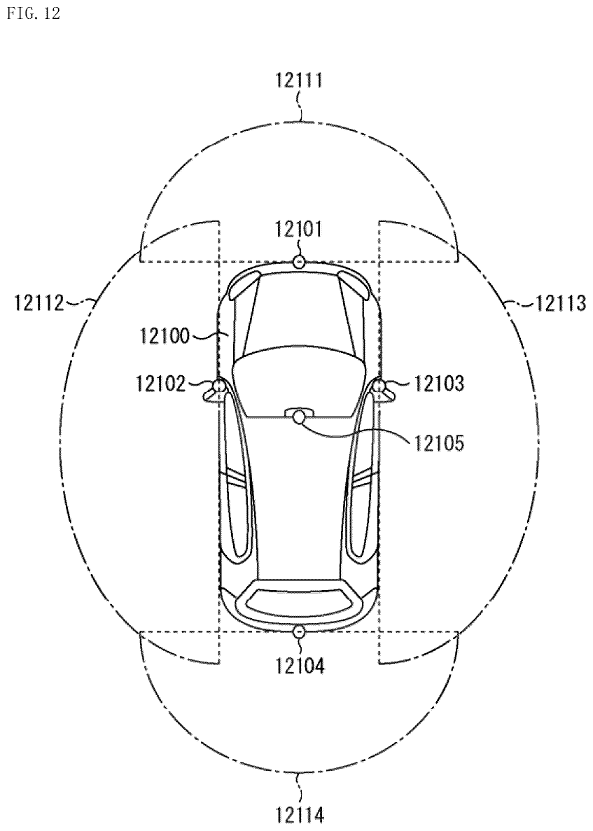

FIG. 12 is a diagram depicting an example of the installation position of the imaging section 12031.

In FIG. 12, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 12 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

As above, there has been described an example of the moving body control system to which the technique according to the present disclosure may be applied. The technique according to the present disclosure may be applied to, of the above-described components, for example, the imaging section 12031. Specifically, the light detection devices (for example, the light detection device 1) according to the above-described embodiment and its modification example are applicable to the imaging section 12031. By applying the technique according to the present disclosure to the imaging section 12031, it becomes possible to obtain a high-definition taken image with less noise; therefore, it is possible to perform high-precision control using the taken image in the moving body control system.

The present technology has been described above with the embodiment, the modification example, and the application examples and the practical application examples: however, the contents of the present disclosure are not limited to the above-described embodiment, etc., and it is possible to make various modifications. For example, in the above-described embodiment, etc., there has been provided an example where electrons are read as a signal charge out from the lower electrode 11 side; however, it is not limited to this, and holes may be read as a signal charge out from the lower electrode 11 side.

Furthermore, in the light detection device 1, etc. described as an example of the light detection device of the present disclosure, the semiconductor substrate 20 may be provided with one or a plurality of photoelectric converters (inorganic photodiodes) that detects light of a different wavelength region from the photoelectric converter 10.

Moreover, in the above-described embodiment, etc., there has been an example of a configuration of a front-illuminated imaging device; however, the contents of the present disclosure are also applicable to a back-illuminated imaging device.

Furthermore, the light detection device 1 and the electronic apparatus 1000 of the present disclosure do not have to include all the components described in the above-described embodiment, etc., and, instead, may include another component. For example, the electronic apparatus 1000 may be provided with a shutter for controlling the entrance of light to the light detection device 1, and may include an optical cut-off filter in accordance with the purpose of the electronic apparatus 1000.

Moreover, in the above-described embodiment, etc., there has been provided an example where the quantum dot 120 is applied to the light detection device 1: however, the quantum dot 120 of the present disclosure may be applied to a solar cell. In a case of application to a solar cell, the photoelectric conversion layer 12 including an ensemble of the quantum dots 120 is preferably designed to absorb, for example, wavelengths of 400 nm to 800 nm in a broad.

It is to be noted that the effects described in the present specification are merely an example, and the effects of the present disclosure are not limited to those, and the present disclosure may have other effects.

It is to be noted that the present technology may have the following configuration. According to the present technology having the following configuration, one or more organic ligands are coordinated to a surface of a core including a compound semiconductor, and a portion of the surface of the core to which the one or more organic ligands are not coordinated is covered with an oxide film. This suppresses a surface defect of a quantum dot, and it is possible to reduce dark current.

(1)

A quantum dot ensemble including a plurality of quantum dots, the plurality of quantum dots each including:
a core including a compound semiconductor; and
a shell layer including one or more organic ligands coordinated to a surface of the core and an oxide film that covers a portion of the surface of the core to which the one or more organic ligands are not coordinated, in which
adjacent quantum dots of the plurality of quantum dots are adjacent through the one or more organic ligands or the oxide film.
   (2)

The quantum dot ensemble according to (1), in which the core includes a compound semiconductor of group IV-VI, III-V, II-VI, I-VI, or I-III-VI or a compound semiconductor including a combination of three or more kinds of elements of groups I, III, IV, V, and VI.

(3)

The quantum dot ensemble according to (1) or (2), in which the one or more organic ligands include one or both of basic group and weak acid group.

(4)

The quantum dot ensemble according to any one of (1) to (3), in which the one or more organic ligands include one or both of thiol group and carboxyl group with a carbon number of 5 or less.

(5)

The quantum dot ensemble according to any one of (1) to (4), in which the one or more organic ligands have a length of 0.6 nm or less.

(6)

The quantum dot ensemble according to any one of (1) to (5), in which the core and the shell layer include the same element.

(7)

The quantum dot ensemble according to (6), in which the oxide film is a surface oxide film of the core.

(8)

The quantum dot ensemble according to (6) or (7), in which the integrated intensity of a first peak derived from bonding of an element having the smallest atomic number among elements included in the core and oxygen through X-ray photoelectron spectroscopic analysis with respect to the integrated intensity of a second peak derived from bonding of the core and the one or more organic ligands is 0.1 or more and 0.3 or less.

(9)

The quantum dot ensemble according to any one of (1) to (8), in which the shell layer has a film thickness of 0.6 nm or less.

(10)

The quantum dot ensemble according to any one of (1) to (9), in which the shell layer has an amorphous structure.

(11)

A light detection device including:
a first electrode;
a second electrode provided to be opposed to the first electrode; and
a photoelectric conversion layer provided between the first electrode and the second electrode, the photoelectric conversion layer including a quantum dot ensemble,
the quantum dot ensemble including a plurality of quantum dots, the plurality of quantum dots each including
   a core including a compound semiconductor, and
   a shell layer including one or more organic ligands coordinated to a surface of the core and an oxide film that covers a portion of the surface of the core to which the one or more organic ligands are not coordinated, in which
adjacent quantum dots of the plurality of quantum dots are adjacent through the one or more organic ligands or the oxide film.
   (12)

An electronic apparatus including a light detection device, the light detection device including:
a first electrode;
a second electrode provided to be opposed to the first electrode; and
a photoelectric conversion layer provided between the first electrode and the second electrode, the photoelectric conversion layer including a quantum dot ensemble,
the quantum dot ensemble including a plurality of quantum dots, the plurality of quantum dots each including
   a core including a compound semiconductor, and
   a shell layer including one or more organic ligands coordinated to a surface of the core and an oxide film that covers a portion of the surface of the core to which the one or more organic ligands are not coordinated, in which
adjacent quantum dots of the plurality of quantum dots are adjacent through the one or more organic ligands or the oxide film.

The present application claims the benefit of Japanese Priority Patent Application JP2022-135014 filed with the Japan Patent Office on Aug. 26, 2022, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A quantum dot ensemble comprising a plurality of quantum dots, the plurality of quantum dots each including:
a core including a compound semiconductor; and
a shell layer including one or more organic ligands coordinated to a surface of the core and an oxide film that covers a portion of the surface of the core to which the one or more organic ligands are not coordinated, wherein
adjacent quantum dots of the plurality of quantum dots are adjacent through the one or more organic ligands or the oxide film.

2. The quantum dot ensemble according to claim 1, wherein the core includes a compound semiconductor of group IV-VI, III-V, II-VI, I-VI, or I-III-VI or a compound semiconductor including a combination of three or more kinds of elements of groups I, III, IV, V, and VI.

3. The quantum dot ensemble according to claim 1, wherein the one or more organic ligands include one or both of basic group and weak acid group.

4. The quantum dot ensemble according to claim 1, wherein the one or more organic ligands include one or both of thiol group and carboxyl group with a carbon number of 5 or less.

5. The quantum dot ensemble according to claim 1, wherein the one or more organic ligands have a length of 0.6 nm or less.

6. The quantum dot ensemble according to claim 1, wherein the core and the shell layer include a same element.

7. The quantum dot ensemble according to claim 6, wherein the oxide film is a surface oxide film of the core.

8. The quantum dot ensemble according to claim 6, wherein integrated intensity of a first peak derived from bonding of an element having a smallest atomic number among elements included in the core and oxygen through X-ray photoelectron spectroscopic analysis with respect to integrated intensity of a second peak derived from bonding of the core and the one or more organic ligands is 0.1 or more and 0.3 or less.

9. The quantum dot ensemble according to claim 1, wherein the shell layer has a film thickness of 0.6 nm or less.

10. The quantum dot ensemble according to claim 1, wherein the shell layer has an amorphous structure.

11. A light detection device comprising:
a first electrode;
a second electrode provided to be opposed to the first electrode; and
a photoelectric conversion layer provided between the first electrode and the second electrode, the photoelectric conversion layer including a quantum dot ensemble,
the quantum dot ensemble including a plurality of quantum dots, the plurality of quantum dots each including
a core including a compound semiconductor, and
a shell layer including one or more organic ligands coordinated to a surface of the core and an oxide film that covers a portion of the surface of the core to which the one or more organic ligands are not coordinated, wherein
adjacent quantum dots of the plurality of quantum dots are adjacent through the one or more organic ligands or the oxide film.

12. An electronic apparatus comprising a light detection device, the light detection device including:
a first electrode;
a second electrode provided to be opposed to the first electrode; and
a photoelectric conversion layer provided between the first electrode and the second electrode, the photoelectric conversion layer including a quantum dot ensemble,
the quantum dot ensemble including a plurality of quantum dots, the plurality of quantum dots each including
a core including a compound semiconductor, and
a shell layer including one or more organic ligands coordinated to a surface of the core and an oxide film that covers a portion of the surface of the core to which the one or more organic ligands are not coordinated, wherein
adjacent quantum dots of the plurality of quantum dots are adjacent through the one or more organic ligands or the oxide film.
